(19) United States
(12) Patent Application Publication
(10) Pub. No.: US 2008/0277718 A1
(43) Pub. Date: Nov. 13, 2008

(54) 1T MEMS scalable memory cell

(76) Inventors: Mihai Adrian Ionescu, Ecublens (CH); Nicolas Abele, Lausanne (CH)

Correspondence Address: NIXON & VANDERHYE, PC, 901 NORTH GLEBE ROAD, 11TH FLOOR, ARLINGTON, VA, 22203, US

(21) Appl. No.: 11/987,413

(22) Filed: Nov. 29, 2007

Related U.S. Application Data
(60) Provisional application No. 60/861,731, filed on Nov. 30, 2006.

(51) Int. Cl. H01L 29/792; H01L 27/12

(52) U.S. Cl. 257/324; 257/347; 257/E29.309; 257/E27.112

(57) ABSTRACT

This invention relates to the use of a gate dielectric placed under the mobile gate electrode of MOS transistor, without the need of a conductive floating gate. The invention exploits the electromechanical hysteretic behavior of the mobile gate when down contacting (pull-in) and up separating (pull-out) from the gate dielectric, based on the (non)equilibrium between electrical and elastic forces.

### CROSS REFERENCE TO RELATED APPLICATION

This application is based on, and claims domestic priority benefits under 35 U.S.C. §119(e) from, Provisional Application No. 60/861,731, filed Nov. 30, 2006, the entire content of which is hereby incorporated by reference.

### BACKGROUND OF THE INVENTION

The invention concerns the integrated circuit domain and, particularly, volatile and non-volatile memories based on Micro-Electro-Mechanical devices.

### BRIEF SUMMARY OF THE INVENTION

Floating gate memory device, like FLASH memory for example, where the memory cell is composed of the following stack: tunnel oxide, storage material and conductive controlling gate over transistor channel was adopted by industry. Charges are stored in a storage material by tunneling through a tunnel oxide when transistor is conducting. Various materials and architectures of such memories have been investigated in the past but some issues still remain:
Leakage current and retention time—As the gate contact is in contact with the storage region, part of the stored charges can migrate through the gate (and tunnel oxide) and generate a gate leakage current. This can negatively impact the memory retention time.
High voltages needed for electron tunneling—Large electric field is needed for electron tunneling to operate the memory, this requirement could be mirrored in a relatively high voltages compared to the small ones available in nanoscale CMOS. An alternative is to use very thin tunnel oxides.

To reduce the leakage through the gate and avoid the need of very thin tunnel oxide, two inventions were disclosed describing the use of an air-gap to inject charges from a suspended conductive gate to an electrically conductive floating gate by the mechanical contact of the two surfaces (U.S. Pat. No. 6,509,605 and U.S. Pat. No. 6,054,745). The two patents describe an architecture where the actuation of the beam with an electrode and the floating gate are two different components used to actuate the gate and store charges under the beam. The separation of the actuation and storage induces a reduction of the memory density.

### BRIEF DESCRIPTION OF THE DRAWINGS

FIG. 1 shows in a) and b) two possible versions of the 1T MEMS memory cell: (a) electromechanical suspended-gate MOSFET cell, (b) electromechanical suspended-gate MOSFET cell with gate storage material.

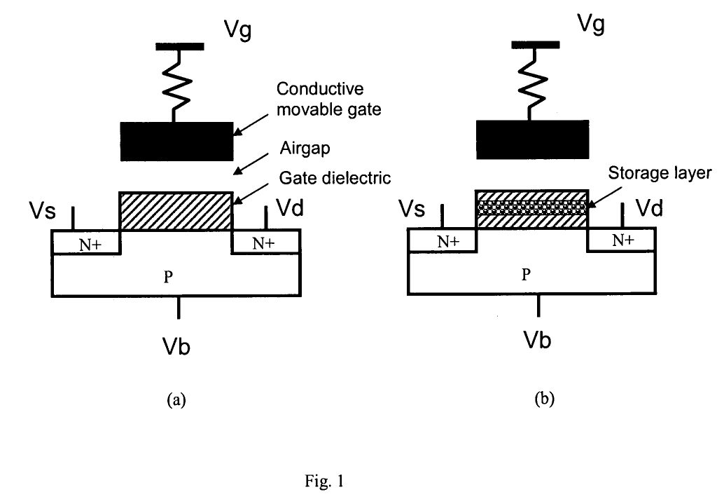

FIG. 2a and b represent respectively cross sections of a suspended gate in the up state (after pull-out) and the down state (after pull-in) of actuation. FIG. 2c shows a top view of clamped-clamped beam design of the device.

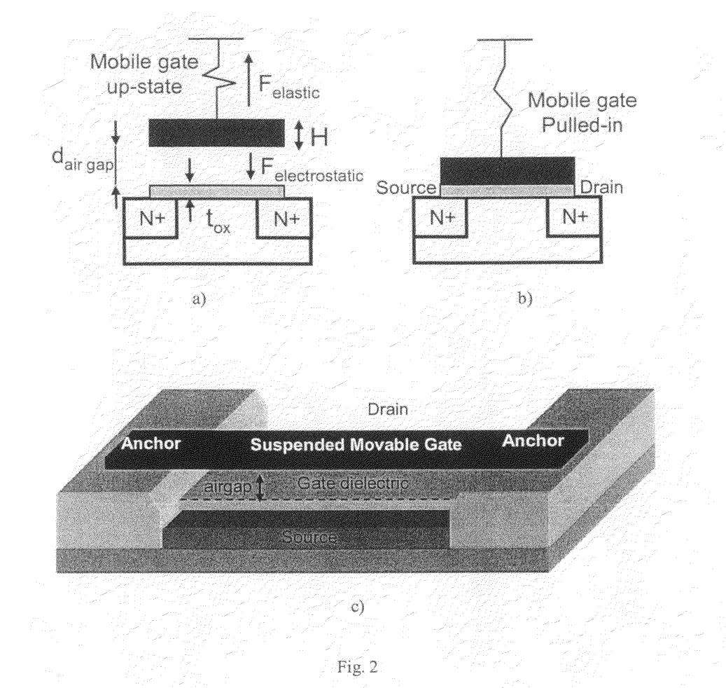

FIG. 3 shows the electromechanical hysteretic behavior of the 1 T MEMS memory cell in case of quasi-negligible charge storage in the gate oxide and operation conditions: Write, Read and Erase. The device can be operated as a volatile (SRAM or DRAM) memory.

FIG. 4 shows the hybrid hysteresis principle using both mechanical effect and charge trapping effect in the gate dielectric to increase the memory window and its operation: Write, Read and Erase. The device can be operated as a non-volatile memory.

### DETAILED DESCRIPTION OF THE INVENTION

This invention proposes a new one transistor (1T) memory cell that overcomes the problem of leakage and meets high density requirements by exploiting a hybrid MEMS-MOS technology. We propose a different principle and approach for a 1T MEMS memory cell, essentially using a suspended-gate MOS transistor.

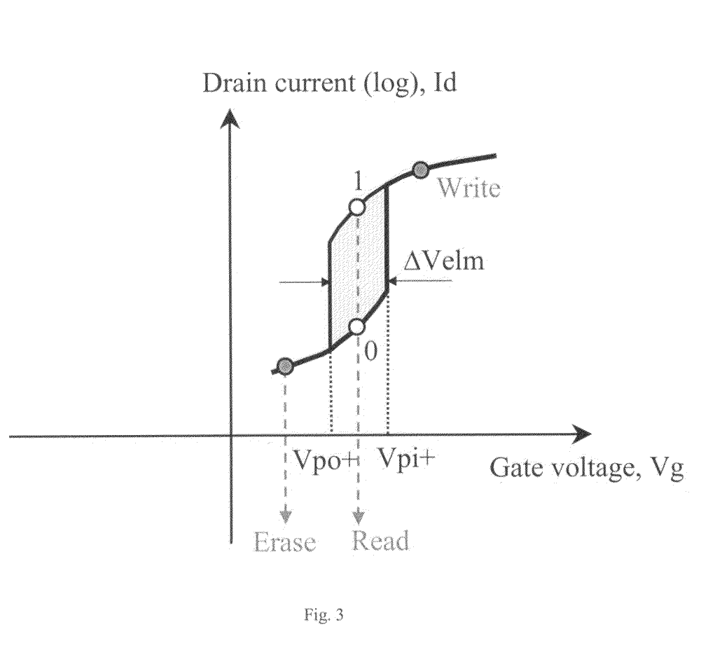

This invention proposes to use a gate dielectric placed under the mobile gate electrode of MOS transistor, without the need of the conductive floating gate mentioned by previous authors. The invention exploits the electromechanical hysteretic behavior of the mobile gate when down contacting (event called pull-in) and up separating (event called pull-out) from the gate dielectric, based on the (non)equilibrium between electrical and elastic forces. The difference between pull-in and pull-out gate voltages defines a significant memory window that can be used in volatile memory applications like SRAM and DRAM. When the gate voltage of mobile gate MOS transistor is increased, an inversion channel forms and the gate is actuated by the electrostatic field under equilibrium up to a non-equilibrium point (pull-in) when the electric force becomes larger than the elastic one and the gate is pulled down at VG=Vpi+ and gets in contact with the dielectric layer of the gate. In the resulting down state the gate capacitance increases significantly and the on current of the transistor also increases very abruptly (FIG. 3). If reducing now back the gate voltage, the initial conditions are changed and the gate voltage condition to restore the up position of the mobile gate, under the action of the elastic force, is reached at a lower than Vpi+ gate voltage, called pulled-out voltage, Vpo+. The inequality Vpi+>Vpo+ results in the hysteresis cycle shown in FIG. 3 in the current-voltage, Id−Vg, characteristics of the MOS transistors and serves the principle proposed for a volatile 1T MEMS memory. The high state (‘1’) is written by applying a gate voltage higher than Vpi+ while the low state (‘0’) of the memory is the stable state corresponding to the gate up. The Read operation of the memory is performed at a voltage that is in between Vpo+ and Vpi+, as shown in FIG. 3

Advantages of the proposed 1T MEMS memory comes form: (i) the 1T compact structure, compatible with CMOS technology, (ii) the scalability of the concept (practically as scalable as the MOS transistor; practically for smaller dimensions of the gate the airgap can be accordingly scaled in order to meet low voltage operation conditions), (iii) the fact that in the up-state (0 memory state in FIG. 3) there is practically no gate leakage current due to the airgap but also the fact that the transistor drain current leakage (under the threshold) is very low because the equivalent threshold voltage of the transistor is very high when the gate is up.

A way to enhance considerably the device hysteresis to obtain non-volatility is proposed in the invention: filling (activating) the dielectric slow traps in the gate insulator instead of using a conductive floating (like in the two mentioned US patents) gate to store charges is proposed for this purpose. The memory device operates in this case based on a novel mechanism called hybrid mechanical—electrical storage hysteresis: an enlarged memory window is obtained, defined in part by the electromechanical operation and, in part by the charge storage. In the case of the hybrid mechanical-electrical hysteresis, the memory cell storage can be non-volatile due to the large retention time of carriers in the dielectric traps or storage material. A storage material layer such as nitride or nanocrystals can be included in the gate dielectric in order to define non-volatility feature.

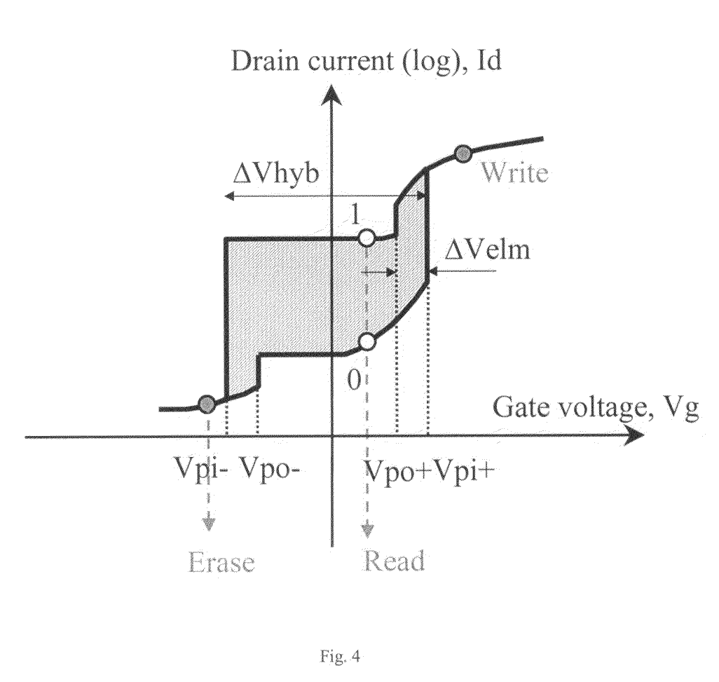

The principle of this second type of operation (called hybrid mechanical-electrical storage hysteresis) operation is depicted in FIG. 4: when the gate is pulled-in by the electrostatic forces, it charges the traps in the oxide or the storage material. These charged traps can then maintain the high-state almost unchanged even if the mechanical pull-out occur at Vpo+ (see FIG. 4). The information can be erased by decreasing in the negative direction the gate voltage: a quasi-symmetrical pull-in occurs this time at negative gate voltage, Vpi− and cancel out the gate charging (because of the opposite electrical field and the electrical contact with the gate dielectric) and restores the initial low states. The Read operation can be performed at a voltage in between Vpi+ and Vpout+, as shown in FIG. 4.

Finally, one should note that in the proposed device operation, the electromechanical displacement under electrostatic actuation and the related electromechanical hysteresis of a mobile-gate transistor are the key principles.

This invention also propose a possible fabrication process flow consisting of patterning an active region in a semiconductor substrate, depositing a dielectric layer and a sacrificial layer on top of this active region. A conductive layer is deposited and patterned to create an anchored gate and releasing this gate by a process allowing the etching of the sacrificial layer selectively to the other materials but degrading the dielectric layer.

1. Memory cell device composed of a suspended gate MOS transistor including a conductive suspended-gate movable above an air-gap, able to move without need of other actuation electrode than the suspended gate electrode, a gate dielectric layer and a semiconductor substrate.

2. Memory cell of claim 1 where the MOS transistor is of n or p-type working in enhancement or accumulation modes.

3. Memory cell of claim 1, where the memory window comes from the difference between mechanical pull-in and pull-out effect and the stored logic levels are directly mirrored in low and high levels of the drain current.

4. Memory cell of claim 1 for which electromechanical hysteresis and charge storage in a gate dielectric and/or a storage layer placed in this dielectric are combined in the same device to increase the hysteresis and, eventually, providing non-volatility of stored information.

5. Memory cell of claim 1, where the suspended gate is a movable conductive beam (metal or doped semiconductor) anchored at one or both ends.

6. Memory cell of claim 1, where the suspended gate is a movable conductive membrane (metal or doped semiconductor) with one or multiple low spring anchors to achieve low voltage operation.

7. Memory cell of claim 1 where the suspended gate is made on one or more silicon nanowires or one or more carbon nanotubes in order to reach high scalability and density at nanoscale.

8. Memory cell of claim 1, made on thin semiconductor film or on a silicon-on-insulator substrate.
